(19) United States
(12) Patent Application Publication
(10) Pub. No.: US 2025/0372415 A1
(43) Pub. Date: Dec. 4, 2025

(54) BONDING MACHINE OF TAPE, BONDING METHOD OF TAPE, AND MANUFACTURING METHOD OF CHIPS

(71) Applicant: DISCO CORPORATION, Tokyo (JP)

(72) Inventors: Masato Shirao, Tokyo (JP); Hiroshi Yoshimura, Tokyo (JP)

(21) Appl. No.: 19/209,344

(22) Filed: May 15, 2025

(30) Foreign Application Priority Data
May 29, 2024 (JP) 2024-087096
Feb. 20, 2025 (JP) 2025-026010

(51) Int. Cl. H01L 21/67; H01L 21/683

(52) U.S. Cl. CPC H01L 21/67132; H01L 21/6836

(57) ABSTRACT

A bonding machine of bonding a self-adhesive tape to an object is provided. The bonding machine includes a holding table configured to hold the object, a frame table configured to support the frame such that the frame opposes the object, a bonding press element configured to press the self-adhesive tape against the object with the self-adhesive tape, the self-adhesive tape being held on the frame, held between the bonding press element and the object, and a bonding and moving mechanism configured to perform bonding press to move the bonding press element and the holding table relative to each other along a direction intersecting a direction of a pressing force of the bonding press element. The frame table is configured to support the frame in a non-parallel state with the holding table upon bonding press.

### BACKGROUND OF THE INVENTION

### Field of the Invention

The present invention relates to a machine and a method of bonding, to an object, a self-adhesive tape bonded on a frame, and also to a manufacturing method of chips with use of the bonding method.

### Description of the Related Art

In manufacturing steps of device chips, an object such as a semiconductor wafer or a package substrate may be handled in a form in which it is bonded on a self-adhesive tape. When a semiconductor wafer is cut, for example, the semiconductor wafer, as an object to be cut, is bonded to a self-adhesive tape. In a form of a frame unit in which the self-adhesive tape is bonded on an annular frame called a “ring frame,” the object is then carried into a processing machine, followed by its processing such as cutting.

The formation of a frame unit is performed, for example, in the following procedures. First, a circular self-adhesive tape is bonded to a ring frame. The self-adhesive tape self-adheres at a peripheral edge portion thereof to the ring frame, and is exposed at a self-adhesive surface thereof in a central opening of the ring frame. To the self-adhesive surface exposed in this opening, a disk-shaped semiconductor wafer is bonded as an object. For bonding work, a roller is used, for example. With the self-adhesive tape held between the roller on one hand and the ring frame and the object on the other hand, the self-adhesive tape is pressed against the ring frame and the object.

Examples of literature that describe technologies relating to such bonding of a self-adhesive tape to a ring frame and an object include JP 2011-86687A, JP 2021-68817A, and so on.

### SUMMARY OF THE INVENTION

When a self-adhesive tape is bonded to an object in such procedures as mentioned above, the self-adhesive tape held on a ring frame is pressed against the object by a roller. Here, a part of a self-adhesive surface of the self-adhesive tape, the part having not been pressed yet by the roller (the part is, of the self-adhesive surface that is exposed in a central opening of the ring frame and is to be bonded to the object, a portion to which the roller has not reached), may come into contact with the object, thereby sticking to the object. As a result, air bubbles may be left between the self-adhesive tape and the object and/or wrinkles may be formed in the self-adhesive tape, so that a frame unit may be formed with insufficient self-adhesion between the self-adhesive tape and the object.

The present invention therefore has as objects thereof the provision of a bonding machine and a bonding method capable of appropriately bonding, to an object, a self-adhesive tape bonded on a frame and a manufacturing method of chips.

In accordance with a first aspect of the present invention, there is provided a bonding machine of bonding a self-adhesive tape to an object. The bonding method includes a holding table configured to hold the object, a frame table configured to support a frame that holds, in such a manner as to surround a self-adhesive surface for the object, the self-adhesive tape to be self-adhered to the object, such that the self-adhesive surface of the self-adhesive tape opposes the object held on the holding table, a bonding press element configured to hold the self-adhesive tape held on the frame, between the bonding press element and the object held on the holding table, and press the self-adhesive tape against the object, and a bonding and moving mechanism configured to perform bonding press to move the bonding press element and the holding table relative to each other along a direction intersecting a direction of a pressing force of the bonding press element. The frame table is configured such that, upon the bonding press, the frame is allowed to be supported in a non-parallel state with the holding table, the non-parallel state being a state where a distance between the self-adhesive tape and the object at a forward position in a moving direction of the bonding press element relative to the holding table is greater than a distance between the self-adhesive tape and the object at a backward position in the moving direction of the bonding press element relative to the holding table.

In the first aspect of the present invention, the frame table may preferably include at least one biasing element configured to bias a portion of the frame supported on the frame table, the portion being forward in the moving direction of the bonding press element relative to the holding table during at least the bonding press, in a direction away from the object held on the holding table, and the at least one biasing element may preferably be configured such that, during the bonding press, the portion of the frame, the portion being forward in the moving direction of the bonding press element relative to the holding table, is operated in a direction toward the object by the pressing force with which the bonding press element presses the frame against the object.

In the first aspect of the present invention, the bonding machine may preferably further include an up-down moving mechanism configured to move the holding table and the frame table relative to each other along a direction intersecting a plane of relative movement of the bonding press element relative to the holding table during the bonding press.

In the first aspect of the present invention, the bonding machine may preferably further include a heating element configured to heat at least one of the bonding press element or the holding table.

In accordance with a second aspect of the present invention, there is provided a bonding method of bonding a self-adhesive tape to an object. The bonding method includes bonding, to a frame, the self-adhesive tape to be self-adhered to the object, such that the frame surrounds a self-adhesive surface for the object, holding the object on a holding table, supporting the frame at such a position where, when the object is held on the holding table and the self-adhesive tape is held on the frame, the self-adhesive surface of the self-adhesive tape opposes the object held on the holding table, and performing bonding press to move the bonding press element and the holding table relative to each other along a direction intersecting a direction of a pressing force of the bonding press element while pressing the self-adhesive tape against the object with the self-adhesive tape, the self-adhesive tape being held on the frame, held between the bonding press element and the object held on the holding table. During the bonding press, the bonding method performs supporting the frame in a non-parallel state with the holding table, the non-parallel state being a state where a distance between the self-adhesive tape and the object at a forward position in a moving direction of the bonding press element relative to the holding table is greater than a distance between the self-adhesive tape and the object at a backward position in the moving direction of the bonding press element relative to the holding table, and bringing a portion of the frame, the portion being forward in the moving direction of the bonding press element relative to the holding table, closer toward the object along with the relative movement of the bonding press element and the object.

In the second aspect of the present invention, when the self-adhesive tape to be bonded to the object is bonded to the frame such that the frame surrounds the self-adhesive surface for the object, the self-adhesive tape may preferably be bonded to the frame in a state where, as seen from a direction orthogonal to the self-adhesive surface of the self-adhesive tape, the self-adhesive surface and a holding surface of the holding table overlap each other and the holding surface of the holding table is located at a recede position apart from the self-adhesive surface in a direction in which the holding surface of the holding table is orthogonal to the self-adhesive surface.

In the second aspect of the present invention, the bonding press may be performed with at least one of the bonding press element or the holding table heated.

In accordance with a third aspect of the present invention, there is provided a manufacturing method of chips using a bonding method of bonding a self-adhesive tape to an object. The bonding method includes bonding, to a frame, the self-adhesive tape to be self-adhered to the object, such that the frame surrounds a self-adhesive surface for the object, holding the object on a holding table, supporting the frame at such a position where, when the object is held on the holding table and the self-adhesive tape is held on the frame, the self-adhesive surface of the self-adhesive tape opposes the object held on the holding table, and performing bonding press to move the bonding press element and the holding table relative to each other along a direction intersecting a direction of a pressing force of the bonding press element while pressing the self-adhesive tape against the object with the self-adhesive tape, the self-adhesive tape being held on the frame, held between the bonding press element and the object held on the holding table. During the bonding press, the bonding method performs supporting the frame in a non-parallel state with the holding table, the non-parallel state being a state where a distance between the self-adhesive tape and the object at a forward position in a moving direction of the bonding press element relative to the holding table is greater than a distance between the self-adhesive tape and the object at a backward position in the moving direction of the bonding press element relative to the holding table, and bringing a portion of the frame, the portion being forward in the moving direction of the bonding press element relative to the holding table, closer toward the object along with the relative movement of the bonding press element and the object. In the manufacturing method, the object is a semiconductor wafer, and the manufacturing method further includes dividing the object into the chips.

According to the tape bonding machine, the tape bonding method, and the chip manufacturing method of the respective aspects of the present invention, the bonding press is performed while, at a part of the self-adhesive surface of the self-adhesive tape, the part being at forward of another part where the bonding by the bonding press element is being performed, in the moving direction of the bonding press element relative to the object, the distance between the self-adhesive tape and the object is maintained greater than at the other part where the bonding by the bonding press element is being performed.

This can effectively prevent the occurrence of premature bonding that, of the self-adhesive surface, the part forward in the moving direction of the bonding press element relative to the object would otherwise come into contact with the object earlier than the part where the self-adhesive tape is held between the bonding press element and the object. Consequently, the self-adhesive tape bonded on the frame can appropriately be bonded to the object.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a side view depicting an example of a configuration of a bonding machine of a self-adhesive tape;

FIG. 2 is an exploded perspective view depicting an example of a configuration of a frame unit formed of an object, the self-adhesive tape, and a frame;

FIG. 3 is a flow chart illustrating an example of procedures relating to a bonding method of the self-adhesive tape and a manufacturing method of chips;

FIG. 4 is a side view depicting a stage in self-adhesive tape bonding that bonds the self-adhesive tape to the frame;

FIG. 5 is a side view depicting another stage in the self-adhesive tape bonding;

FIG. 6A is a side view depicting a stage in final bonding that bonds, to the object, the self-adhesive tape bonded on the frame;

FIG. 6B is a plan view of the state of FIG. 6A as seen from another direction;

FIG. 7A is a side view depicting another stage in the final bonding;

FIG. 7B is a plan view of the state of FIG. 7A as seen from another direction;

FIG. 8A is a side view depicting still another stage in the final bonding;

FIG. 8B is a plan view of the state of FIG. 8A as seen from another direction; and

FIG. 9 is a side view depicting a stage in the manufacture of the chips.

### DETAILED DESCRIPTION OF THE PREFERRED EMBODIMENT

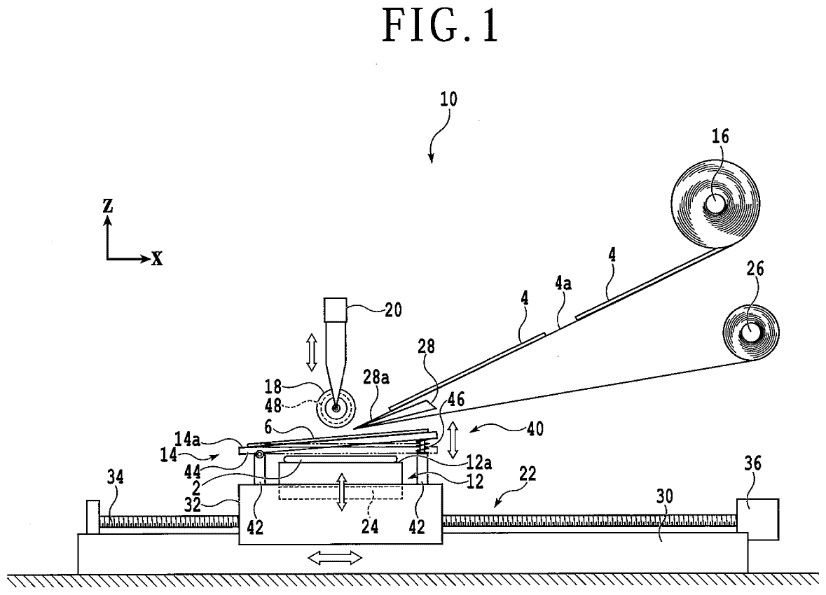

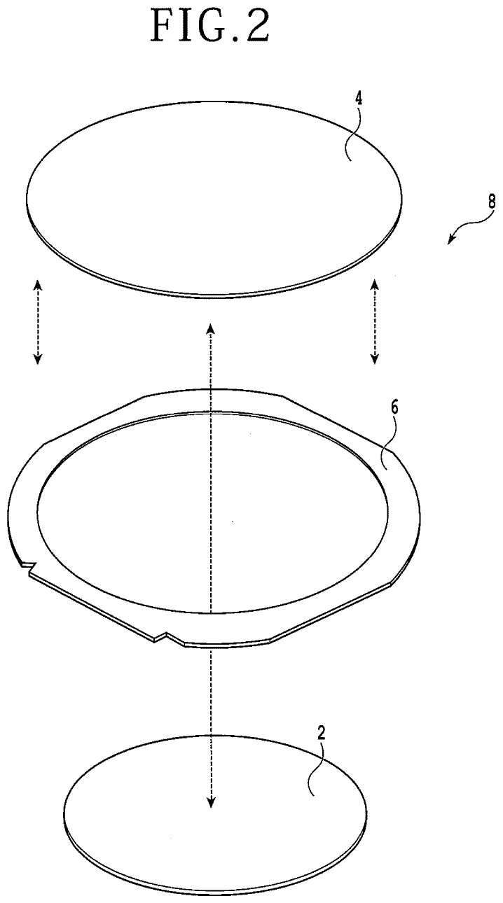

With reference to the attached drawings, a description will be made in detail with regard to an embodiment of the present invention. FIG. 1 is a side view depicting a configuration of a bonding machine of a self-adhesive tape according to this embodiment, and FIG. 2 is an exploded perspective view depicting an example of a configuration of a frame unit formed using the bonding machine.

As depicted in FIG. 2, a frame unit 8 is formed using an object 2, a self-adhesive tape 4, and a frame 6 as constituent elements. However, one or more components other than the foregoing can also be included further as constituent elements of the frame unit 8.

The object 2 is, for example, a disk-shaped semiconductor wafer, a package substrate, or the like. However, an item of a shape or a type other than the foregoing can also be handled as the object 2.

The self-adhesive tape 4 is a sheet-shaped component formed including one side (the side on a lower side in FIG. 2) as a self-adhesive surface. The base material that makes up the self-adhesive tape 4 is, for example, a thin, resin-made, flexible sheet. On one side of the sheet, a self-adhesive material is stacked to form a self-adhesive layer. It is to be noted that depiction of a release sheet is omitted in FIG. 2 although the self-adhesive surface of the self-adhesive tape 4 that has not yet been used is covered by the release sheet.

It is also to be noted that components of a planar shape may be referred to in different terms, for example, “sheets,” “films,” or the like, depending on their thicknesses, but components of a planar shape are herein all simply called “sheets” without exception irrespective of the values of their specific thicknesses.

The frame 6 is a plate-shaped member having a shape that includes an opening in a central region and surrounds the opening. As the frame 6, an annular frame called a “ring frame” is depicted here in some of the figures. However, the frame 6 is not necessarily required to be annular, and is simply needed to have such a shape as surrounding the central region. For example, the frame 6 can be formed as a C-shaped component.

On the frame 6, the self-adhesive surface of the circular self-adhesive tape 4 is bonded at a peripheral edge portion thereof. A central part of the self-adhesive surface (the central part corresponding to the central region of the frame 6, which is formed as the opening) is not bonded on the frame 6, and is left exposed. To this central part, the object 2 is bonded.

In this manner, the frame 6 is bonded to the self-adhesive tape 4 in such a manner as to surround the self-adhesive surface of the self-adhesive tape 4.

Consequently, the frame unit 8 is formed in such a form that the self-adhesive tape 4 is held on the frame 6 and the object 2 is bonded on the self-adhesive surface, which is surrounded by the frame 6, of the self-adhesive tape 4.

Now, when a frame unit is formed by an object, a self-adhesive tape, and a frame, there are a few kinds of procedures as procedures to bond the self-adhesive tape, including, for example, a method of bonding the object to the self-adhesive tape after bonding the self-adhesive tape to the frame and a method of bonding the self-adhesive tape concurrently to the frame and the object. In this embodiment in particular, performed is the method of bonding the object to the self-adhesive tape after bonding the self-adhesive tape to the frame. Bonding procedures will be mentioned in detail subsequently herein.

A bonding machine 10 of this embodiment as depicted in FIG. 1 is configured to be capable of performing the bonding of the self-adhesive tape 4 to the frame 6 (hereinafter called “self-adhesive tape bonding” for convenience) and the bonding of the object 2 to the self-adhesive tape 4 held on the frame 6 (hereinafter called “final bonding”).

The bonding machine 10 includes a holding table 12 for holding the object 2, a frame table 14 for supporting the frame 6, and a tape holder 16 for holding the self-adhesive tape 4, which is to be bonded to the object 2 and the frame 6, such that it can be paid out. The bonding machine 10 further includes a bonding press element 18, a pressing mechanism 20, a bonding and moving mechanism 22, an up-down moving mechanism 24, a take-up device 26, and a release plate 28.

The holding table 12 is a table to hold the object 2 such as a semiconductor wafer, and is, for example, a chuck table that holds the object 2 by suction using a negative pressure by an undepicted system. The holding table 12 has an upper surface, which is configured as a holding surface 12a for holding the object 2 thereon.

The frame table 14 is a table which is disposed surrounding the holding table 12 and supports the frame 6 at an adequate height relative to the holding table 12 and the object 2. The frame table 14 has an upper surface formed as a support surface 14a to support the frame 6.

When the final bonding is performed to bond the self-adhesive tape 4 to the object 2, the frame 6 is supported in such a manner as to surround the object 2 which is held on the holding surface 12a of the holding table 12, as seen in plan view (at a point of view from a Z-direction to be mentioned subsequently herein), and to be located slightly closer in the Z-direction to the bonding press element 18 than the object 2 (in other words, above the object 2) (their positional relation will be mentioned again in detail subsequently herein). In this embodiment, the frame table 14 is configured to also support the frame 6 when the self-adhesive tape bonding is performed to bond the self-adhesive tape 4 to the frame 6.

The tape holder 16 holds a roll of self-adhesive tapes 4 wound in a roll form. The self-adhesive tapes 4 that have not yet been used are held on a release sheet 4a in such a form that their self-adhesive layers are in contact with one side of the release sheet 4a, and is wrapped along with the release sheet 4a in the roll form. The self-adhesive tapes 4 that have not yet been used, which are in the form of a wrapped roll, are held at a portion thereof corresponding to a central axis of the roll on the tape holder 16. The self-adhesive tapes 4 are configured such that, when one of the self-adhesive tapes 4 is bonded to the frame 6, the release sheet 4a is paid out in a tangential direction from an outer peripheral portion of the roll with the roll rotating relative to the tape holder 16.

The bonding press element 18 is, for example, a roller having a cylindrical rolling surface. The axis of rotation of the bonding press element 18 as the roller is set to extend along a direction parallel with a surface (upper surface) of the object 2 held on the holding table 12, the surface opposing the self-adhesive tape 4, and also in a direction along a direction (Y-direction; a direction orthogonal to the paper plane of FIG. 1) orthogonal to a moving direction (X-direction) of the bonding and moving mechanism 22 to be described subsequently herein.

When the bonding press is performed to bond the self-adhesive tape 4 to the frame 6 or the object 2, the bonding press element 18 is configured to be pressed against the frame 6 or the object 2 by the pressing mechanism 20. The pressing mechanism 20 is a mechanism for pressing the bonding press element 18 and the object 2 relative to and against each other, and in this embodiment, is configured to support the bonding press element 18 and also to operate the bonding press element 18 up and down (along the Z-direction).

Although depiction of a detailed construction and the like of the pressing mechanism 20 is omitted, the pressing mechanism 20 is configured to apply a force in a direction (in a direction along a vertical direction (Z-direction)) toward the holding table 12 or the frame table 14 relative to the bonding press element 18 by a construction using, for example, a hydraulic pressure, a pneumatic pressure, a resilient force, or the like, and hence to press the bonding press element 18 against the frame 6 or the object 2 with an appropriate force. As a consequence, the bonding press element 18 presses the self-adhesive tape 4 against the object 2.

It is to be noted that the bonding press element 18 is not limited to such a roller as described herein and can be any component insofar as it can perform the bonding work by appropriately pressing the self-adhesive tape 4. For example, the bonding press element 18 does not rotate relative to the self-adhesive tape 4, the frame 6, and the object 2, and may be such a component that slides relative to them and presses the self-adhesive tape 4.

Further, the mechanism or the system that presses the self-adhesive tape 4 against the object 2 by the bonding press element 18 is not limited to such a mechanism that moves the bonding press element 18 up and down. For example, the holding table 12 may be caused to slide in the X-direction while supporting the bonding press element 18, which is the roller, at a specific position and maintaining the object 2 in contact with the bonding press element 18.

If the bonding press element 18, which is the roller, is formed of a flexible material or such a mechanism or system as to bias the bonding press element 18 toward the object 2 is included, the self-adhesive tape 4 can be pressed against the object 2 with the bonding press element 18 by causing the object 2 to slide relative to the bonding press element 18 supported at the specific position.

The bonding and moving mechanism 22 is a mechanism for moving the bonding press element 18 and the holding table 12 relative to each other along a direction (X-direction) intersecting the direction of a pressing force of the bonding press element 18, and is hence configured to perform the bonding press of the self-adhesive tape 4 against the object 2 (final bonding). The bonding and moving mechanism 22 is also configured to perform the bonding press of the self-adhesive tape 4 against the frame 6 through a similar operation (self-adhesive tape bonding).

The bonding and moving mechanism 22 includes a pair of movement rails 30 disposed on a bottom portion of a frame that forms the bonding machine 10 and a movable table 32 that moves along the movement rails 30.

The movement rails 30 are a pair of plate-shaped members disposed in parallel with each other along a horizontal direction (of the paired movement rails 30, only one movement rail 30 located on the nearer side is seen in FIG. 1), and the movable table 32 is arranged slidably along a length direction of the movement rails 30 on upper surfaces of the movement rails 30. Between the paired movement rails 30, a ball screw 34 is arranged in parallel with an extending direction of the movement rails 30.

An undepicted nut portion is disposed on a lower portion of the movable table 32, and the ball screw 34 extends through the nut portion and is in meshing engagement with the nut portion. To one end portion of the ball screw 34, a pulse motor 36 is attached. The ball screw 34 is rotated by operation of the pulse motor 36, and the movable table 32 is moved along the movement rails 30.

On an upper surface of the movable table 32, the holding table 12 and the frame table 14 are arranged, and accompanied with movement of the movable table 32, the holding table 12 and the frame table 14 move along the horizontal direction. The direction along the moving direction of the movable table 32 is herein defined as the “X-direction.”

In this embodiment, the mechanism that presses the bonding press element 18 against the object 2 and the frame 6 has been described as the pressing mechanism 20. As a replacement for or an addition to this mechanism, such a mechanism that presses the object 2 and the frame 6 against the bonding press element 18 may be adopted.

Similarly, the mechanism that moves the object 2 and the frame 6 relative to the bonding press element 18 has been described as the bonding and moving mechanism 22 in this embodiment. As a replacement for or an addition to this mechanism, such a mechanism that moves the bonding press element 18 may be adopted.

Further, such expressions as “along a direction parallel with the surface” and a “direction along the vertical direction” are used herein. However, these expressions do not necessarily mean only cases where the directions of both strictly coincide or are strictly parallel with each other. For example, a case where both extend at a small angle to each other and in substantially the same direction may also be included.

The movable table 32 includes a mount section for the holding table 12. In this mount section, the up-down moving mechanism 24 is disposed. The up-down moving mechanism 24 is a mechanism for moving the holding table 12 and the frame table 14 relative to each other along a direction (Z-direction, vertical direction) intersecting the plane of relative movement of the bonding press element 18 to the holding table 12 upon bonding press, and is configured to be capable of moving the holding table 12 in the Z-direction between a bonding position where the position in the Z-direction of the holding surface 12a of the holding table 12 is close to the support surface 14a of the frame table 14 and a recede position where the holding surface 12a of the holding table 12 is apart in the Z-direction from the support surface 14a of the frame table 14.

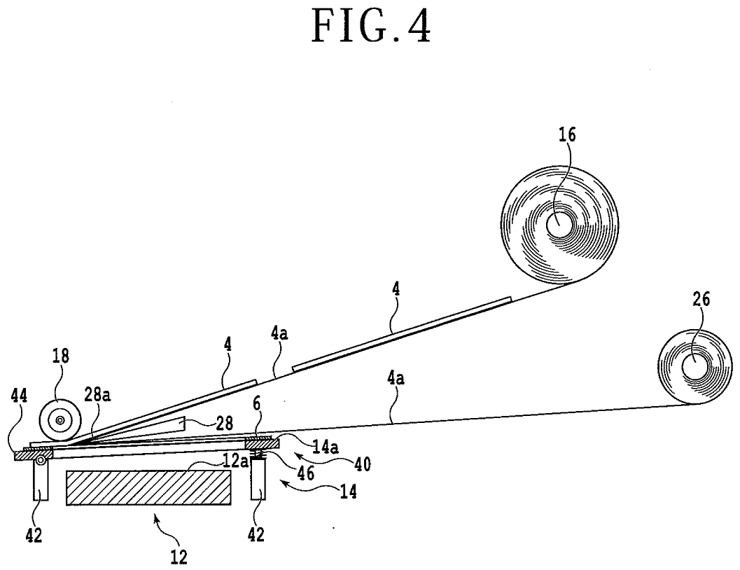

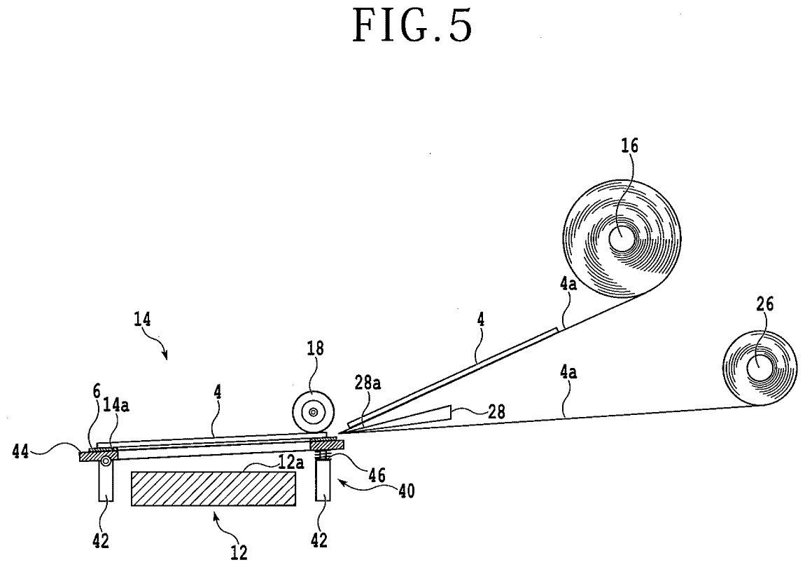

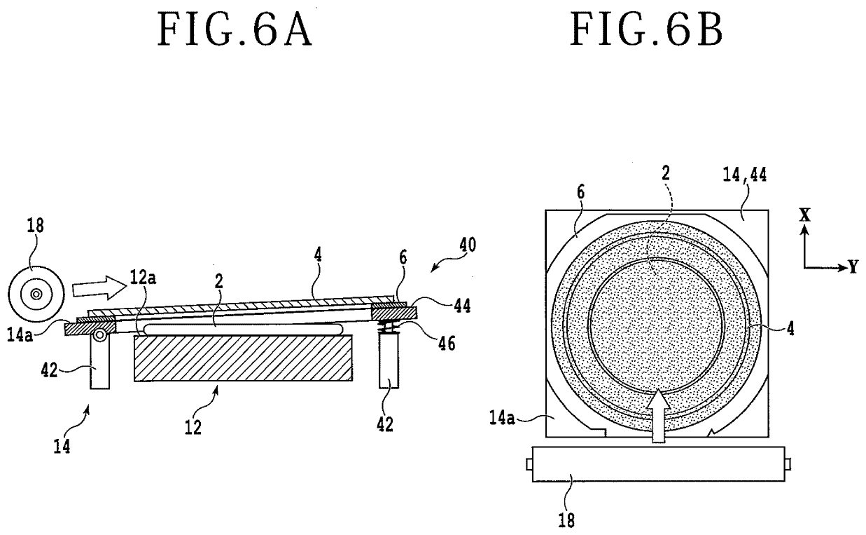

A description will be made with regard to the bonding position and the recede position. In this embodiment, when the above-mentioned frame unit 8 (see FIG. 2) is formed, the self-adhesive tape 4 is first bonded to the frame 6 (self-adhesive tape bonding; see FIGS. 4 and 5), and the object 2 is then bonded to the self-adhesive surface of the self-adhesive tape 4 (final bonding; see FIGS. 6A to 8B).

In the process of the final bonding (see FIGS. 6A to 8B), the object 2 is bonded to the self-adhesive tape 4 with the frame 6 bonded thereon, specifically, to the self-adhesive surface of the same self-adhesive tape 4, and therefore, there is a need to bring the height (the position in the Z-direction) of an upper surface of the frame 6 (the surface to be bonded to the self-adhesive tape 4) and that of the upper surface of the object 2 (the surface to be bonded to the self-adhesive tape 4) close to each other. In other words, the term “bonding position” indicates a positional relation in which the holding table 12 and the frame table 14 are relatively close to each other in the Z-direction to make it possible to bond the object 2 to the self-adhesive tape 4 bonded on the frame 6.

In the preceding process of the self-adhesive tape bonding (see FIGS. 4 and 5), the self-adhesive tape 4 is bonded to the frame 6 supported on the support surface 14a of the frame table 14. If the frame 6 and the holding table 12 are close to each other in the Z-direction at this time, there arises a concern regarding the possibility of bonding of parts of the self-adhesive surface of the self-adhesive tape 4 to the holding table 12.

The self-adhesive tape 4 is formed with a sheet-shaped flexible base material, and the bonding press element 18, which is the roller to be used for bonding, also has a certain degree of flexibility. Upon the bonding press in the self-adhesive tape bonding, a portion of the bonding press element 18 may protrude together with the self-adhesive tape 4 toward the holding table 12, which is located below the opening of the frame 6, depending on conditions such as the pressing force applied to the bonding press element 18, the dimensions of the thickness of the frame 6 and the diameter of its opening, and the base material of the bonding press element 18.

If the holding table 12 is not sufficiently apart from the frame 6 at this time, the self-adhesive tape 4 that has protruded downward from the frame 6 sticks to the upper surface (holding surface 12a) of the holding table 12. To prevent this, when the self-adhesive tape bonding is performed, the holding surface 12a of the holding table 12 is receded to a position downwardly apart from the support surface 14a of the frame table 14 on which the frame 6 is supported (to a side opposite in the Z-direction to an upper position where the bonding press element 18 and the self-adhesive tape 4 are located). In other words, the term “recede position” indicates the positional relation in which the holding table 12 and the frame table 14 are relatively apart in the Z-direction from each other to prevent the holding table 12 from sticking to the self-adhesive tape 4 when the self-adhesive tape 4 is bonded to the frame 6.

Upon the final bonding (see FIGS. 6A to 8B), the object 2 is held on the holding surface 12a, that is, the upper surface of the holding table 12, and the object 2 is bonded to the self-adhesive surface, that is, the lower surface of the self-adhesive tape 4 bonded on the upper surface of the frame 6, so that the upper surface of the object 2 held on the holding table 12 and the upper surface of the frame 6 on which the self-adhesive tape 4 is bonded are at substantially the same height (at substantially the same position in the Z-direction).

If, upon the self-adhesive tape bonding (see FIGS. 4 and 5), the holding table 12 and the frame table 14 are placed in the same positional relation (at the same bonding positions) as in the final bonding, the upper surface (holding surface) 12a of the holding table 12 is therefore apart by substantially the thickness of the object 2 from the self-adhesive surface of the self-adhesive tape 4 that is held on the frame 6 supported on the support surface 14a of the frame table 14.

Nonetheless, the bonding of the self-adhesive tape 4 to the upper surface (holding surface) 12a of the holding table 12 occurs if the amount of protrusion in the Z-direction of the self-adhesive tape 4 from the frame 6 during the bonding press increases to the thickness of the object 2 or greater. It is hence preferred to move the holding table 12 to the recede position when the self-adhesive tape bonding is performed.

Concerning the movement of the holding table 12 between the bonding position and the recede position, the case where the holding table 12 is moved relative to the frame table 14 has been described here. However, the frame table 14 may be moved instead of the holding table 12, or both the holding table 12 and the frame table 14 may be moved.

In this embodiment, the frame table 14 is provided with a tilting mechanism 40 in such a manner as to support the frame 6 in a tilted state upon the bonding press. The tilting mechanism 40 is a mechanism of, for example, such a construction as will be mentioned hereinafter.

The frame table 14 includes a plurality of support posts 42 disposed such that they project upward from the upper surface of the movable table 32 and a tabletop 44 supported as a top plate on the support posts 42. An upper surface of the tabletop 44 forms the support surface 14a of the frame table 14.

The tabletop 44 is connected at a lower surface thereof to upper ends of the support posts 42. At one or some of connecting portions between the tabletop 44 and the support posts 42, the connecting portion or portions being backward in a moving direction of the bonding press element 18 relative to the holding table 12 (on a left side of the holding table 12 in FIG. 1) in the bonding press, the tabletop 44 is turnably attached to the corresponding support post or posts 42. Described more specifically, the tabletop 44 is connected to the support post or posts 42 via a hinge-like connection structure or hinge-like connection structures in such a manner as to be able to turn about an axis along the horizontal direction (Y-direction; the direction of the axis of rotation of the bonding press element 18 as the roller) that is orthogonal to the moving direction (X-direction) of the bonding and moving mechanism 22.

On the other hand, at one or some of the connecting portions between the tabletop 44 and the support posts 42, the connecting portion or portions being forward in the moving direction of the bonding press element 18 relative to the holding table 12 in the bonding press, the tabletop 44 is attached movably up and down (along the Z-direction) to the corresponding support post or posts 42.

As the bonding press element 18 moves from left to right relative to the holding table 12 (the holding table 12 moves from right to left when seen from the bonding press element 18) during the bonding press in the example depicted in FIG. 1 and FIGS. 4 to 8B, the term “backward” as used herein indicates the left side in the figures, and the term “forward” as used herein indicates a right side in the figures. Arrow marks in FIGS. 6A to 8B indicate the moving directions of the bonding press element 18 as seen from the side of the holding table 12, the frame table 14, the object 2, or the frame 6.

One or some of the support posts 42, the support post or posts 42 being forward (on the right side in the figures) in the moving direction of the bonding press element 18, is or are provided with a biasing element 46 or biasing elements 46 between the support post or posts 42 and the tabletop 44 to bias the tabletop 44 upward from the corresponding support post or posts 42. If no external force is applied, the tabletop 44 rises slightly above the upper end or ends of such support post or posts 42 by the total biasing force or forces of the corresponding biasing element or elements 46.

As described above, with respect to the support post or posts 42 located on the left side in the figures, the tabletop 44 is connected to the upper end or ends of the support post or posts 42 via the hinge-like structure or structures, and with respect to the support post or posts 42 located on the right side in the figures, on the other hand, the tabletop 44 is supported via the biasing element or elements 46 in such a manner as to rise slightly above the top end or ends of the support post or posts 42.

Consequently, a portion of the frame 6 supported on the frame table 14, the portion being forward in the moving direction of the bonding press element 18 relative to the holding table 12 during the bonding press, is biased in a direction away from the holding table 12 and the object 2 supported on the holding table 12.

In a state where such an external force as opposing the total biasing force or forces of the biasing element or elements 46 is not applied, or in a state where such an external force is sufficiently small compared with the total biasing force or forces of the biasing element or elements 46, the tabletop 44 and the frame 6, as depicted by solid lines in FIG. 1, rise at portions thereof on the right side in the figure relative to portions thereof on the left side in the figure, whereby the tabletop 44 and the frame 6, as a whole, are supported in a tilted non-parallel state with the movable table 32.

When the bonding press is performed by the bonding press element 18 to bond the self-adhesive tape 4 to the frame 6 on the frame table 14 and the object 2 on the holding table 12, the portions of the tabletop 44 and the frame 6, the portions being forward in the moving direction of the bonding press element 18 relative to the holding table 12, are configured to be operated in a direction toward the object 2 by the pressing force with which the bonding press element 18 presses the frame 6 against the object 2.

Now, the term “non-parallel state” as used herein, if the final bonding step is assumed, indicates a state where the distance between the self-adhesive tape 4 (the self-adhesive tape 4 bonded on the frame 6) and the object 2 (the object 2 held on the holding table 12 during the final bonding) at a forward position (on the right side in FIGS. 1, 4, 5, 6A, 7A, and 8A) in the moving direction of the bonding press element 18 relative to the holding table 12 is greater than the distance between the self-adhesive tape 4 and the object 2 at a backward position in the moving direction of the bonding press element 18 relative to the holding table 12 (on the left side in FIGS. 1, 4, 5, 6A, 7A, and 8A) and a state where the frame 6 is supported in such a manner as to maintain the self-adhesive tape 4 and the object 2 in such a non-parallel positional relation.

When the tabletop 44 is depressed with a sufficient force against the total biasing force or forces of the biasing element or biasing elements 46, the portion of the lower surface of the tabletop 44, the portion being located on the right side in FIGS. 6A, 7A, and 8A, moves downward (if the state where the object 2 is held on the holding table 12 is assumed, in the direction in which the frame 6 supported on the tabletop 44 comes closer toward the object 2), and comes into contact with the upper end or ends of the corresponding support post or posts 42. In this state, the tabletop 44 and the frame 6 supported on the tabletop 44 are as a whole supported in substantially parallel with an X-Y plane as indicated by two-dot chain lines in FIG. 1.

As a construction to bias the tabletop 44 by the biasing element or elements 46, a resilient element or elements such as, for example, a coil spring or springs can be used. As a construction to support the frame 6 in the non-parallel state by the tilting mechanism 40 and as a construction to bias the tabletop 44 by the biasing element or elements 46, any constructions may be adopted insofar as they can support the frame 6 in the non-parallel state during the final bonding and can cancel the non-parallel state by an external force. In addition, a construction, for example, by a hydraulic pressure, a pneumatic pressure, an electromagnetic force, or the like can also be assumed.

The description has now been made of the example in which the frame 6 is supported in the non-parallel state by providing one or some of the support posts 42, which constitute leg portions of the frame table 14, with the biasing element or elements 46, and locally raising the tabletop 44 there to tilt the tabletop 44 as a whole. As an alternative, the tabletop 44 may be tilted, for example, by providing all the support posts 42 with the biasing elements 46, respectively, and supporting the tabletop 44 at different heights among the biasing elements 46. In this manner, the self-adhesive tape 4 can be pressed with a stronger force against the frame 6 or the object 2 by applying a pressing force from the pressing mechanism 20 such that the pressing force opposes the total biasing forces exerted by the respective biasing elements 46.

The take-up device 26 and the release plate 28 are used when the self-adhesive tape bonding is performed. Reference is now made to FIGS. 4 and 5. When the self-adhesive tape 4 is bonded to the frame 6, the self-adhesive tapes 4 wrapped along with the release sheet 4a in a roll form are held on the tape holder 16 located above a forward position (on the right side in the figures) as seen from the holding table 12 in the moving direction of the bonding press element 18 relative to the holding table 12, and each self-adhesive tape 4 is paid out along with the release sheet 4a from the tape holder 16 toward the holding table 12.

The bonding press element 18 is located above the frame 6 supported on the frame table 14, and the release plate 28 is arranged between the bonding press element 18 and the frame 6 and at a forward position in the moving direction of the bonding press element 18 relative to the holding table 12 as seen from the bonding press element 18.

The release plate 28 is a plate-shaped member having a pointed triangular cross-section as depicted in FIGS. 1, 4 and 5, and extends in the direction (Y-direction) orthogonal to the paper plane of FIGS. 1, 4 and 5. Upon the self-adhesive tape bonding, the release plate 28 is arranged, at a position presented in FIGS. 4 and 5, in such a posture that a portion (called a “releasing edge 28a”), which is formed to become thinner toward an end portion located on a left side in FIGS. 1, 4 and 5, is held between the bonding press element 18 and the upper surface of the frame 6.

During the self-adhesive tape bonding, the take-up device 26 is supported above a forward position (the right side in the figures) in the moving direction of the bonding press element 18 relative to the holding table 12, and at a position that is lower than that of the tape holder 16 as seen from the holding table 12. During the self-adhesive tape bonding, the release sheet 4a paid out along with the self-adhesive tape 4 from the tape holder 16 is carried to the release plate 28, folded back at the releasing edge 28a of the release plate 28, carried to the take-up device 26, and then taken up there.

The release sheet 4a is folded back at the releasing edge 28a of the release plate 28, but the self-adhesive tape 4, which has been carried from the tape holder 16 to the release plate 28 in the state of being bonded on the upper surface of the release sheet 4a, does not follow the release sheet 4a folded back at the releasing edge 28a, is allowed to remain on the upper surface of the frame 6, and is bonded to the frame 6.

By adjusting the paying-out rate of the release sheet 4a and the self-adhesive tapes 4 at the tape holder 16 and the take-up rate of the release sheet 4a at the take-up device 26, the tensions of the release sheet 4a between the tape holder 16 and the release plate 28 and between the release plate 28 and the take-up device 26 are adjusted.

In the bonding press element 18, a heating element 48 (see FIG. 1) is incorporated to heat an outer peripheral surface (the surface that comes into contact with the self-adhesive tape 4 upon the self-adhesive tape bonding or the final bonding) of the bonding press element 18. The heating element 48 is, for example, an electrically energized heater.

When the self-adhesive tape 4 is bonded to the frame 6 or the object 2, the self-adhesiveness may be improved if the base material that makes up the self-adhesive tape 4 is heated to a certain degree of temperature. In this embodiment, therefore, there is adopted a configuration in which, upon the self-adhesive tape bonding or the final bonding, the temperature of the self-adhesive tape 4 can be raised by heating the bonding press element 18 with the heating element 48. Instead of or in addition to the heating element 48 included in the bonding press element 18, a heating element may be provided in such a way as being incorporated, for example, in the holding table 12.

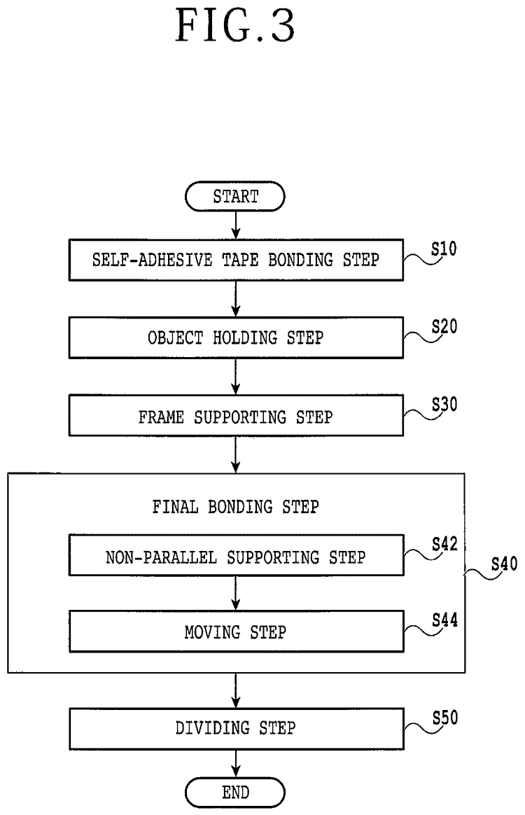

Operation of this embodiment described above will next be described with reference to a flow chart of FIG. 3 and FIGS. 4 to 8B. FIGS. 4 and 5 are side views depicting different stages, respectively, of the self-adhesive tape bonding that bonds the self-adhesive tape 4 to the frame 6. FIGS. 6A to 8B present different stages, respectively, in the final bonding that bonds, to the object 2, the self-adhesive tape 4 bonded on the frame 6. FIGS. 6A, 7A, and 8A are side views, and FIGS. 6B, 7B, and 8B are plan views.

First, a self-adhesive tape bonding step is performed to bond the self-adhesive tape 4 to the frame 6 (Step S10). As depicted in FIGS. 4 and 5, the frame 6 as the annular frame (ring frame) is supported on the support surface 14a of the frame table 14, and the self-adhesive tape 4 is held between the bonding press element 18, which is located above the frame 6, and the frame 6.

The bonding press element 18 and the frame 6 are pressed relative to and against each other by the pressing mechanism 20 with the self-adhesive tape 4 held therebetween, and at the same time, the bonding press element 18 and the frame 6 are moved relative to each other along the X-direction by operation of the bonding and moving mechanism 22 (in this embodiment, the bonding press element 18 is pressed against the frame 6, and the movable table 32 with the frame table 14 arranged thereon is moved relative to the bonding press element 18).

Upon the self-adhesive tape bonding, the self-adhesive tape 4 is paid out along with the release sheet 4a from the tape holder 16. The release sheet 4a is folded back at the releasing edge 28a of the release plate 28 arranged between the bonding press element 18 and the frame 6, carried to the take-up device 26, and taken up there.

As depicted in FIGS. 4 and 5, the self-adhesive tape 4 on the frame 6 is held between the bonding press element 18 and the frame 6. While being pressed in the Z-direction by the pressing mechanism 20, the self-adhesive tape 4 is moved along with the frame 6 in the X-direction relative to the bonding press element 18 by operation of the bonding and moving mechanism 22, and is progressively bonded to the upper surface of the frame 6.

The releasing edge 28a of the release plate 28 is located between the bonding press element 18 and the frame 6 and at a slightly forward position, in the moving direction of the bonding press element 18 relative to the frame 6, of a position where the bonding press element 18 comes into contact with the frame 6 with the self-adhesive tape 4 held therebetween.

Concurrently with relative movement in the X-direction of the frame 6 and the bonding press element 18 (in this embodiment, movement of the frame 6 from right to left relative to the bonding press element 18 in the figures), the release sheet 4a is progressively taken up on the take-up device 26 over a length corresponding to the amount of the movement.

The self-adhesive tape 4 held on the side of the upper surface of the release sheet 4a does not follow the movement of the release sheet 4a folded back at the releasing edge 28a of the release plate 28 and to be taken up on the take-up device 26, and is allowed to remain on the frame 6 and is held between the bonding press element 18 and the frame 6. When this operation is performed from the side of one end to the side of the other end of the single self-adhesive tape 4 in the X-direction, the single self-adhesive tape 4 is brought into a state of being bonded on the upper surface of the frame 6.

During this self-adhesive tape bonding step, the holding table 12 is moved to the position downwardly apart relative to the self-adhesive surface of the self-adhesive tape 4 to be bonded to the frame 6 (the recede position).

In other words, while the self-adhesive tape 4 is being bonded to the frame 6, the holding table 12 is at the recede position where the self-adhesive surface and the holding surface 12a overlap each other as seen in the direction (Z-direction) orthogonal to the self-adhesive surface of the self-adhesive tape 4 and the holding surface 12a is apart from the self-adhesive surface in the Z-direction. This makes it possible to perform the bonding of the self-adhesive tape 4 to the frame 6 while preventing the self-adhesive surface of the self-adhesive tape 4 from being bonded to the holding surface 12a of the holding table 12.

On the holding table 12, the object 2 is held (object holding step; Step S20). On the holding surface 12a of the holding table 12 as the chuck table, the object 2 such as the disk-shaped wafer is held.

On the frame table 14, the frame 6 with the self-adhesive tape 4 bonded thereon is supported (frame holding step; Step S30). The self-adhesive tape 4 to be bonded to the object 2 is held on the frame 6 such that the frame 6 surrounds the self-adhesive surface for the object 2. The frame 6 is supported on the frame table 14 such that the self-adhesive surface opposes the object 2. On the upper surface of the frame 6, the self-adhesive tape 4 is held in such a posture that the self-adhesive surface is directed downward, and on a lower side of the self-adhesive tape 4, the object 2 to which the self-adhesive tape 4 is to be bonded is located.

In the frame supporting step, the frame 6 is therefore supported at a position where, when the object 2 is held on the holding table 12 and the self-adhesive tape 4 is supported on the frame 6, the self-adhesive surface of the self-adhesive tape 4 opposes the object 2 held on the holding table 12.

The description has now been made in the order of the self-adhesive tape bonding step (Step S10), the object holding step (Step S20), and the frame supporting step (Step S30). Concerning these steps, however, their sequence is not limited to the sequence described here. For example, the self-adhesive tape bonding step may be performed after the frame supporting step, and the object holding step may be performed before the self-adhesive tape bonding step (in this case, sufficient space may desirably be left between the self-adhesive tape 4 and the object 2 by the up-down moving mechanism 24 such that the self-adhesive tape 4 does not stick the object 2 in the self-adhesive tape bonding step).

After the object 2 has been held on the holding table 12 and the frame 6 with the self-adhesive tape 4 bonded thereon has been supported on the frame table 14, a final bonding step is performed to bond, to the object 2, the self-adhesive tape 4 bonded on the frame 6 (Step S40).

In the final bonding step, as depicted in FIGS. 6A to 8B, the self-adhesive tape 4 which is held on the frame 6 in the way that the self-adhesive surface is bonded at a part thereof to the frame 6 is held between the bonding press element 18 and the object 2 held on the holding table 12, and bonding press is then performed to bond the self-adhesive tape 4 to the object 2. While the bonding press element 18 and the object 2 are pressed relative to and against each other by the pressing mechanism 20, the bonding press element 18 and the holding table 12 are moved relative to each other along the direction (X-direction) intersecting the direction of the pressing force exerted by the bonding press element 18 (the direction of the pressing force exerted by the bonding press element 18 to the object 2; Z-direction).

In the final bonding step (Step 40), a non-parallelly supporting step (Step S42) is further performed to adjust the posture of the frame 6 in accordance with the progress of the bonding of the self-adhesive tape 4 to the object 2, and at the same time, a moving step (Step S44) is also performed.

At the initiation of the final bonding step (Step S40), the frame 6 is supported by the biasing element or elements 46 in the non-parallel state where the distance between the self-adhesive tape 4 and the object 2 at the forward position (the right side in FIG. 6A) in the moving direction of the bonding press element 18 relative to the holding table 12 is greater than the distance between the self-adhesive tape 4 and the object 2 at the backward position (the left side in FIG. 6A) in the moving direction (the non-parallelly supporting step; Step S42).

When the bonding press element 18 is moved relative to the object 2 in the X-direction by the bonding and moving mechanism 22 while being pressed against the object 2 by the pressing mechanism 20 with the self-adhesive tape 4 held therebetween (in the case of this embodiment, the object 2 is progressively moved relative to the bonding press element 18 by movement of the movable table 32), a portion of the tabletop 44 with the frame 6 supported thereon, the portion being located forward in the moving direction of the bonding press element 18 relative to the holding table 12, is progressively depressed against the total biasing force or forces of the biasing element or elements 46 by the pressing force of the pressing mechanism 20.

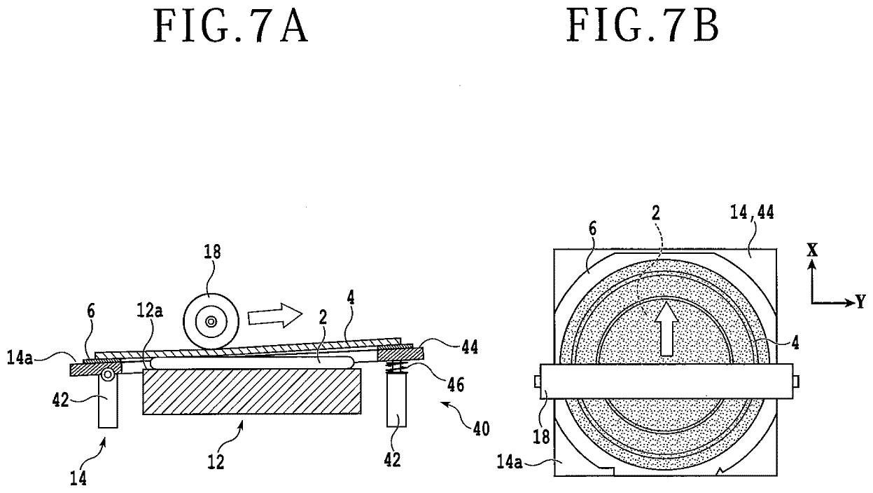

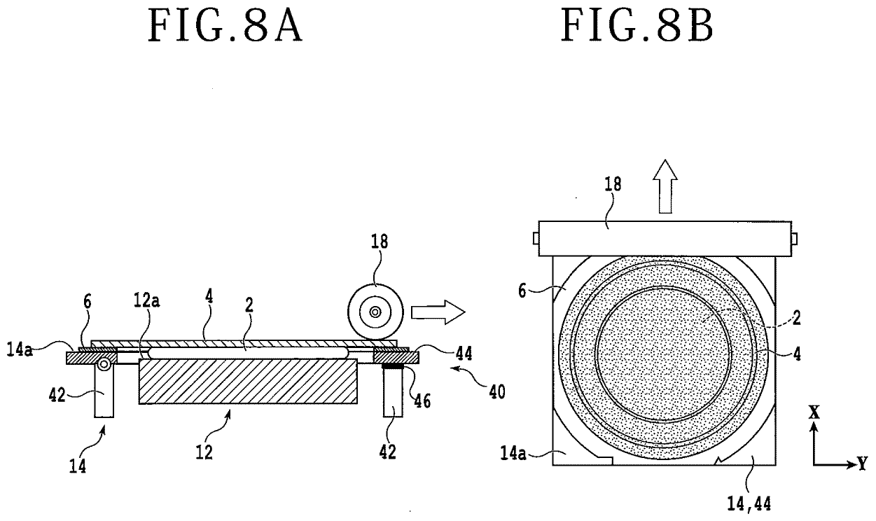

In other words, upon the bonding press that is performed in the final bonding step (Step S40), the frame 6 is supported in the non-parallel state in the beginning as depicted in FIG. 6A, but along with the relative movement of the bonding press element 18 and the object 2, the portion of the frame 6, the portion being forward in the moving direction of the bonding press element 18 relative to the holding table 12, is gradually brought closer to the object 2 as depicted in FIGS. 7A and 8A (the moving step; Step S44).

If the bonding press by the bonding press element 18 is performed with the frame 6 and the object 2 maintained in a parallel state with each other when the final bonding is performed to bond the object 2 to the self-adhesive tape 4 bonded on the frame 6, a part of the self-adhesive surface, the part being forward in the moving direction of the bonding press element 18 relative to the object 2, may come into contact with the object 2 earlier (this is called “premature bonding” for convenience), depending on the conditions of the self-adhesive tape 4, than another part of the self-adhesive surface at which the self-adhesive tape 4 is held between the bonding press element 18 and the object 2 (the part at which the bonding by the bonding press element 18 is being performed).

If premature bonding occurs, the self-adhesive surface includes an unbonded part between a part where the premature bonding has occurred and another part where the bonding by the bonding press element 18 is being performed by the bonding press element 18, and therefore, the bonding by the bonding press element 18 is further performed to eliminate the unbonded part. A possibility that, in this region, air bubbles are left between the self-adhesive tape 4 and the object 2 and/or wrinkles are be formed in the self-adhesive tape 4 may hence arise.

In this embodiment, therefore, upon the final bonding, the bonding press is performed with the frame 6 supported in a non-parallel state, in such a manner as to make non-parallel the self-adhesive tape 4 and the upper surface of the object 2.

With the configuration described above, at the part of the self-adhesive surface of the self-adhesive tape 4, the part being forward of the part where the bonding by the bonding press element 18 is being performed, in the moving direction of the bonding press element 18 relative to the object 2, the distance between the self-adhesive tape 4 and the object 2 is greater than at the part where the bonding by the bonding press element 18 is being performed. Consequently, the contact between the self-adhesive surface of the self-adhesive tape 4 and the object 2 can be avoided except at the parts of the self-adhesive surface of the self-adhesive tape 4, the parts being the part where the bonding by the bonding press element 18 is being performed and the part where the bonding by the bonding press element 18 has been finished, so that the occurrence of premature bonding can effectively be prevented.

In the final bonding, however, it is necessary that, eventually, the object 2 and the self-adhesive tape 4 come out of the non-parallel state and be brought into a state where the self-adhesive surface of the self-adhesive tape 4 is, in its entirety, in contact with the upper surface of the object 2. As a mechanism for supporting the frame 6 in the non-parallel state, the tilting mechanism 40 with the biasing element or elements 46 included therein is therefore disposed in this embodiment.

At the initiation of the final bonding, the tilting mechanism 40 raises the portion of the tabletop 44 by the total biasing force or forces of the biasing element or elements 46 to tilt the frame 6, whereby the self-adhesive tape 4 is held in the non-parallel state. As the bonding press proceeds in the final bonding, the tabletop 44 is progressively depressed against the total biasing force or forces of the biasing element or elements 46 by the bonding press element 18. As a consequence, the frame 6 comes out of the non-parallel state, and assumes a posture that maintains the self-adhesive surface of the self-adhesive tape 4 and the object 2 in close contact with each other, thereby ensuring to sufficiently and completely perform the bonding between them.

In the non-parallel state, the frame 6 is supported in such a posture that the self-adhesive surface of the self-adhesive tape 4 is tilted relative to the upper surface of the object 2 to which the self-adhesive surface is to be bonded. Here, the angle and distance between them need to fall within adequate ranges, respectively, because premature bonding is prone to occur if the angle and/or distance between them are too small, and if too large, on the other hand, a problem arises in the bonding itself of the self-adhesive tape 4 to the object 2.

In a case where the object 2 is a wafer of 300 mm in diameter, for example, the distance between the upper surface of the frame 6 with the self-adhesive tape 4 held thereon and an upper surface of the object 2, to which the self-adhesive tape 4 is to be bonded, may be set to 100 μm or greater but 1 mm or smaller (for example, approximately 400 μm) at a most forward position in the moving direction of the bonding press element 18 relative to the object 2, although this distance varies depending on the material and the thickness of the self-adhesive tape 4, the pressing force to be applied to the bonding press element 18 by the pressing mechanism 20, the material of the bonding press element 18, and so on.

During the period from the initiation of the final bonding to shortly before its completion, the self-adhesive tape 4 basically remains in the non-parallel state with the object 2 (with the tilting angle gradually varying concomitantly with the movement of the bonding press element 18). If the bonding press element 18 is formed with a material having flexibility as mentioned above, by the pressing force of the pressing mechanism 20, a portion of the bonding press element 18 protrudes downward from the upper surface of the frame 6, and at the same time, the self-adhesive tape 4 is depressed. This makes it possible to bring the self-adhesive surface of the self-adhesive tape 4 into contact with the object 2 and to bond them to each other, even if there is a slight distance between the upper surface of the frame 6 and the upper surface of the object 2 due to the support of the self-adhesive tape 4 in the non-parallel state.

Upon completion of the final bonding, it is desired from the standpoint of suitably performing the bonding that the upper surface of the object 2 and the upper surface of the frame 6 to both of which the self-adhesive tape 4 has been bonded are in a flush state. Before the final bonding is performed, the positions in the Z-direction of the bonding press element 18 and the holding table 12, the position where the tabletop 44 of the frame table 14 is supported by the tilting mechanism 40 and the biasing element or elements 46, and the like may preferably be adjusted such that the upper surface of the object 2 and the upper surface of the frame 6 come into flush upon completion of the final bonding.

As a mechanism for maintaining the self-adhesive tape 4 and the object 2 in a non-parallel state and allowing them to come out of the non-parallel state, an appropriate mechanism can be adopted without being limited to the above-mentioned construction by the biasing element or elements 46. For example, such a construction that the angle of the frame 6 can be adjusted without relying upon a pressing force may be adopted instead of the above-mentioned construction that, according to the pressing force of the bonding press element 18, the tabletop 44 with the frame 6 supported thereon is depressed and the tilting angle of the tabletop 44 is changed. For example, such a construction that the height or heights of the support post or posts 42 for the frame table 14, that is, the tilting angle of the tabletop 44, is changed by a hydraulic pressure or the like can be assumed.

If, during the performance of the self-adhesive tape bonding or the final bonding, the bonding press element 18 is heated by the heating element 48 and the self-adhesive tape 4 is heated to a suitable temperature, the self-adhesiveness of the self-adhesive tape 4 for the frame 6 or the object 2 increases, and the formation of the frame unit 8 (see FIG. 2) by bonding can suitably be performed. If a heating element is included in the holding table 12, the object 2 held on the holding table 12 may be heated by the heating element upon the final bonding, thereby raising the temperature of the self-adhesive tape 4 maintained in close contact with the object 2.

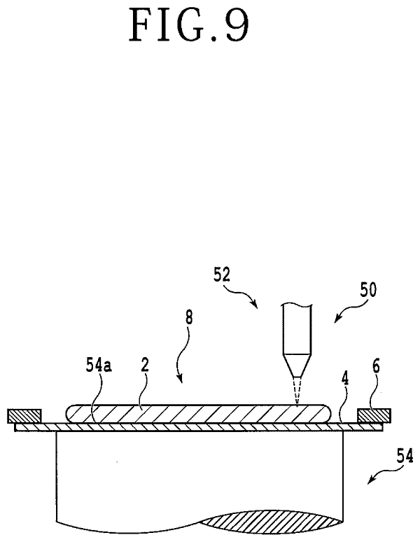

After the frame unit 8 has been formed as described above, the object 2 as the semiconductor wafer is divided into individual chips to manufacture device chips (dividing step; Step S50). FIG. 9 is a side view depicting a stage (dividing step) in the manufacture of chips.

In the dividing step (Step S50), a laser processing machine 50 such as one depicted in FIG. 9, for example, is used, and a laser beam is applied to the object (wafer) 2 to divide the wafer 2.

The laser processing machine 50 includes an irradiation unit 52 for irradiating the wafer 2 with the laser beam and a holding mechanism 54 for holding the wafer 2.

The irradiation unit 52 is a system that guides and focuses the laser beam which has been emitted from an undepicted laser oscillator, by an undepicted optical system including an undepicted lens, an undepicted mirror, and the like, and that applies the focused laser beam to the wafer 2 held on the holding mechanism 54.

The holding mechanism 54 is, for example, a chuck table, and is configured to hold the wafer 2 as the object by suction. The holding mechanism 54 has an upper surface, which is formed as a holding surface 54a for holding the wafer 2. To the holding surface 54a, a negative pressure is supplied from an undepicted supply source, whereby the wafer 2 as the object is attracted by suction on the holding surface 54a. To a lower portion of the holding mechanism 54, a rotating mechanism (not depicted in the figure) is connected to rotate the holding mechanism 54 about an axis of rotation along the vertical direction.

The frame unit 8 with the wafer 2 included therein is held on the holding surface 54a of the holding mechanism 54, and a laser beam of a wavelength having absorptivity for the material of the wafer 2 is applied. The laser beam is applied after an adjustment through the focusing lens, which is disposed in the irradiation unit 52, so as to have a focal point at an intended position on the wafer 2.

By moving the holding mechanism 54 and the irradiation unit 52 relative to each other in a direction along the holding surface 54a while the wafer is applied with the laser beam, ablation processing is progressively applied to the wafer 2 along scribe lines set in a grid pattern on the wafer 2. In this manner, the wafer 2 is divided into the individual chips to manufacture the device chips.

When the device chips are manufactured as described above, the wafer 2 as the object is bonded, in the frame unit 8, to the self-adhesive tape 4 in a good state where there are neither many wrinkles in the self-adhesive tape 4 nor many air bubbles and the like between the wafer 2 and the self-adhesive tape 4. The occurrence of such problems as a reduction in processing accuracy due to wrinkles and the like and separation of chips due to the occurrence of unbonded parts by air bubbles or the like is suppressed, and therefore, chips can be manufactured with high quality and yield.

In the dividing step (Step S50), by such a method that an external force is applied after grooves have been formed along the scribe lines in the wafer 2 by laser ablation processing, the wafer 2 may be divided along the grooves, or after modified layers have been formed along the scribe lines in the material of the wafer 2 by application of a laser beam, the wafer 2 may be divided along the modified layers.

As a further alternative, the dividing step S50 may also be performed using a cutting machine. The cutting machine includes, for example, a cutting unit and a holding mechanism.

The cutting unit includes a spindle with a cutting blade fitted thereon and a housing with the spindle rotatably supported thereon. The cutting blade includes, for example, an annular hub base and an annular cutting blade attached to and along an outer peripheral edge of the hub base.

The spindle is formed in a circular column shape, and includes, on the side of one end thereof, a blade mounter with the cutting blade mounted thereon and, on the side of the other end thereof, a rotary drive source such as a motor. The spindle of the circular column shape is accommodated in the housing such that its axis extends along the horizontal direction, and by operation of the rotary drive source, rotates together with the cutting blade about the axis along the horizontal direction.

When cutting is performed, the cutting blade is caused to cut into the wafer 2 held on the holding mechanism, while being allowed to rotate together with the spindle. With the cutting blade cutting in the wafer 2, the cutting unit and the holding mechanism are moved relative to each other in a direction along a holding surface, so that the wafer 2 is progressively divided along the scribe lines. After cut grooves have been formed along the scribe lines in the wafer 2 by the cutting blade, the wafer 2 may also be divided along the cut grooves by such a method as applying an external force.

When the device chips are manufactured from the wafer 2, other processing such as ultraviolet irradiation and film formation, for example, may also be appropriately performed before or after the division.

The construction, the method, and the like according to the above-mentioned embodiment are not limited to only the above-described embodiment, and can appropriately be changed or modified insofar as not departing from the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A bonding machine of bonding a self-adhesive tape to an object, comprising:
a holding table configured to hold the object;
a frame table configured to support a frame that holds, in such a manner as to surround a self-adhesive surface for the object, the self-adhesive tape to be self-adhered to the object, such that the self-adhesive surface of the self-adhesive tape opposes the object held on the holding table;
a bonding press element configured to hold the self-adhesive tape held on the frame, between the bonding press element and the object held on the holding table, and press the self-adhesive tape against the object; and
a bonding and moving mechanism configured to perform bonding press to move the bonding press element and the holding table relative to each other along a direction intersecting a direction of a pressing force of the bonding press element,
wherein the frame table is configured such that, upon the bonding press, the frame is allowed to be supported in a non-parallel state with the holding table, the non-parallel state being a state where a distance between the self-adhesive tape and the object at a forward position in a moving direction of the bonding press element relative to the holding table is greater than a distance between the self-adhesive tape and the object at a backward position in the moving direction of the bonding press element relative to the holding table.

2. The bonding machine according to claim 1,
wherein the frame table includes at least one biasing element configured to bias a portion of the frame supported on the frame table, the portion being forward in the moving direction of the bonding press element relative to the holding table during at least the bonding press, in a direction away from the object held on the holding table, and
the at least one biasing element is configured such that, during the bonding press, the portion of the frame, the portion being forward in the moving direction of the bonding press element relative to the holding table, is operated in a direction toward the object by the pressing force with which the bonding press element presses the frame against the object.

3. The bonding machine according to claim 1, further comprising:
an up-down moving mechanism configured to move the holding table and the frame table relative to each other along a direction intersecting a plane of relative movement of the bonding press element relative to the holding table during the bonding press.

4. The bonding machine according to claim 2, further comprising:
an up-down moving mechanism configured to move the holding table and the frame table relative to each other along a direction intersecting a plane of relative movement of the bonding press element relative to the holding table during the bonding press.

5. The bonding machine according to claim 1, further comprising:
a heating element configured to heat at least one of the bonding press element or the holding table.

6. The bonding machine according to claim 2, further comprising:
a heating element configured to heat at least one of the bonding press element or the holding table.

7. A bonding method of bonding a self-adhesive tape to an object, comprising:
bonding, to a frame, the self-adhesive tape to be self-adhered to the object, such that the frame surrounds a self-adhesive surface for the object;
holding the object on a holding table;
supporting the frame at such a position where, when the object is held on the holding table and the self-adhesive tape is held on the frame, the self-adhesive surface of the self-adhesive tape opposes the object held on the holding table; and
performing bonding press to move the bonding press element and the holding table relative to each other along a direction intersecting a direction of a pressing force of the bonding press element while pressing the self-adhesive tape against the object with the self-adhesive tape, the self-adhesive tape being held on the frame, held between the bonding press element and the object held on the holding table,
wherein, during the bonding press, the bonding method performs
supporting the frame in a non-parallel state with the holding table, the non-parallel state being a state where a distance between the self-adhesive tape and the object at a forward position in a moving direction of the bonding press element relative to the holding table is greater than a distance between the self-adhesive tape and the object at a backward position in the moving direction of the bonding press element relative to the holding table, and
bringing a portion of the frame, the portion being forward in the moving direction of the bonding press element relative to the holding table, closer toward the object along with the relative movement of the bonding press element and the object.

8. The bonding method according to claim 7, wherein, when the self-adhesive tape to be bonded to the object is bonded to the frame such that the frame surrounds the self-adhesive surface for the object, the self-adhesive tape is bonded to the frame in a state where, as seen from a direction orthogonal to the self-adhesive surface of the self-adhesive tape, the self-adhesive surface and a holding surface of the holding table overlap each other and the holding surface of the holding table is located at a recede position apart from the self-adhesive surface in a direction in which the holding surface of the holding table is orthogonal to the self-adhesive surface.

9. The bonding method according to claim 7, wherein the bonding press is performed with at least one of the bonding press element or the holding table heated.

10. The bonding method according to claim 8, wherein the bonding press is performed with at least one of the bonding press element or the holding table heated.

11. A manufacturing method of chips using a bonding method of bonding a self-adhesive tape to an object, the bonding method including
bonding, to a frame, the self-adhesive tape to be self-adhered to the object, such that the frame surrounds a self-adhesive surface for the object,
holding the object on a holding table,
supporting the frame at such a position where, when the object is held on the holding table and the self-adhesive tape is held on the frame, the self-adhesive surface of the self-adhesive tape opposes the object held on the holding table, and
performing bonding press to move the bonding press element and the holding table relative to each other along a direction intersecting a direction of a pressing force of the bonding press element while pressing the self-adhesive tape against the object with the self-adhesive tape, the self-adhesive tape being held on the frame, held between the bonding press element and the object held on the holding table,
during the bonding press, the bonding method performing
supporting the frame in a non-parallel state with the holding table, the non-parallel state being a state where a distance between the self-adhesive tape and the object at a forward position in a moving direction of the bonding press element relative to the holding table is greater than a distance between the self-adhesive tape and the object at a backward position in the moving direction of the bonding press element relative to the holding table, and
bringing a portion of the frame, the portion being forward in the moving direction of the bonding press element relative to the holding table, closer toward the object along with the relative movement of the bonding press element and the object,
wherein the object is a semiconductor wafer, and
the manufacturing method further includes dividing the object into the chips.
